(19) United States
(12) Patent Application Publication
(10) Pub. No.: US 2003/0119282 A1
(43) Pub. Date: Jun. 26, 2003

(54) Method for producing semiconductor fine particles

(76) Inventor: Takayasu Yamazaki, Minami-ashigara-shi (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/247,617

(22) Filed: Sep. 20, 2002

(30) Foreign Application Priority Data
Sep. 20, 2001 (JP) 287191/2001
Sep. 20, 2001 (JP) 287192/2001

(51) Int. Cl. C23C 16/00; C30B 1/00; H01L 21/00

(52) U.S. Cl. 438/478; 438/800; 427/255.33; 427/255.5

(57) ABSTRACT

Disclosed is a method for producing semiconductor fine particles comprising a step of preparing two or more solutions each containing at least one element selected from Group II to Group VI and feeding the solutions to an addition tank with mixing the two or more solutions fed to the addition tank by stirring to produce fine particles. In this production method, (1) flows of different rotational directions are formed by stirring the two or more solutions fed to the addition tank, and/or (2) a solvent is introduced into the addition tank beforehand, a mixing chamber having an opening is disposed below liquid surface of the solvent in the addition tank, and the two or more solutions are fed to the mixing chamber with controlling flow rates of the solutions. According to this production method, semiconductor fine particles having uniform grain sizes can be produced in a simple and convenient manner.

### TECHNICAL FIELD

The present invention relates to a novel method for producing semiconductor fine particles having uniform particle sizes.

### RELATED ART

Remarkable progress has been made in the semiconductor industry to such an extent that almost no equipments or systems can exist without semiconductors at present. While silicon constitutes the mainstream of today's semiconductors, compound semiconductors have been noted in recent years due to the needs of higher processing speed and so forth. In the field of optoelectronics, for example, compound semiconductors play a leading role, and most of studies about light-emitting devices, photoelectric conversion elements, various lasers, nonlinear optical devices and so forth concern compound semiconductors. For example, Group II-VI compounds, which consist of a combination of a Group II element such as Zn and Cd and a Group VI element such as O and S, are known to have an excellent luminescence (fluorescence) characteristic, and applications thereof to various fields are expected.

Meanwhile, these materials are generally used as particles having uniform particle sizes in order to more effectively obtain their performances. Moreover, in recent years, the need for material development based on nanotechnology has been strongly recognized, and even finer particles of the aforementioned materials are also desired. The term “nanotechnology” used herein means techniques of manipulating and regulating atoms and molecules in the micro world in a scale of one millionth millimeter to utilize substance characteristics unique to nanosize substances (e.g., quantum effect) and thereby obtain their novel functions and excellent performances. The nanotechnology is not only important as a research field in itself, but also important in applied research fields of, for example, light-emitting devices, photoelectric conversion elements, various lasers, nonlinear optical devices and so forth. It is considered that a major part of conventional production and processing techniques will shift to nanotechnology techniques within the 21st century.

Under such circumstances, there are a large number of references concerning synthesis methods of nanosize semiconductor particles and examples of their applications. For example, Japanese Patent Laid-open Publication (Kokai) No. 2000-104058 reported that use of a nanosize particle fluorescent substance prepared by the coprecipitation method markedly increased light emission efficiency. It is expected that, in such fluorescent particles, particle size distribution in addition to the median particle size would greatly affect the light emission efficiency. That is, among fluorescent material particles showing a broad size distribution, it is difficult for particles having a size larger than the median size to exert the quantum effect, and in addition, amount per unit volume of the activating agent serving as emission centers increases. On the other hand, as for particles of a size smaller than the median size, activation magnitude per unit volume decreases, and therefore emission efficiency of individual particles fluctuates. Under such a situation, if a fluorescent material showing a narrow size distribution can be prepared and used, further improvement of the efficiency can be expected without suffering from fluctuation of the efficiency of individual particles.

Further, J. Am. Chem. Soc., 1993, 115, 8706-15 describes that a dispersion of nanometer size CdSe particles could be prepared in a liquid phase and their absorption spectrum was changed by the quantum size effect. This article is an outstanding literature, because it suggested particles having a narrow size distribution could be prepared by fractionating particles according to particle size while monitoring results of absorption spectrum measurement of particles, and further the quantum effect depending on the particle size could be directly confirmed. However, the procedure of this method is quite complex in spite of the use of liquid phase for the preparation, and further, it takes a long period of time. Therefore, it would be extremely significant to develop a simple and convenient novel method for producing semiconductor fine particles showing a narrow particle size distribution.

An object of the present invention is to provide a simple and convenient novel method for producing semiconductor fine particles having uniform particle sizes. Another object of the present invention is to provide a method for producing semiconductor fine particles showing a narrow particle size distribution and superior dispersibility.

### SUMMARY OF THE INVENTION

The present invention provides a method for producing semiconductor fine particles comprising a step of preparing two or more solutions each containing at least one element selected from Group II to Group VI and separately or simultaneously feeding the solutions to an addition tank with mixing the two or more solutions fed to the addition tank by stirring to produce fine particles comprising two or more elements selected from Group II to Group VI, which satisfies the following Requirements (1) and/or (2).

Requirement (1)

Flows of different rotational directions should be formed by stirring the two or more solutions fed to the addition tank.

Requirement (2)

A solvent should be introduced into the addition tank beforehand, a mixing chamber having an opening should be disposed below liquid surface of the solvent in the addition tank, and the two or more solutions should be fed to the mixing chamber with controlling flow rates of the solutions.

In preferred embodiments of the method of the present invention, two solutions each containing at least one element selected from Group II to Group VI are prepared and Requirement (1) is satisfied; as the solutions each containing at least one element selected from Group II to Group VI, a first solution of a compound containing at least one Group II element or Group III element and a second solution of a compound containing at least one Group V element or Group VI element are prepared and Requirement (2) is satisfied; as the solutions each containing at least one element selected from Group II to Group VI, a first solution of a compound containing at least one Group II element and a second solution of a compound containing at least one Group VI element are prepared; fine particles comprising a Group II element and a Group VI element are prepared as the semiconductor fine particles; at least one of the two or more solutions contains at least one element selected from transition metals and rare earth metals; at least one of the two or more solutions contains an anionic surfactant and/or nonionic surfactant; at least one of the two or more solutions contains a polymerizable organic compound or polymer; a solution containing a polymerizable organic compound or polymer is fed to the addition tank to which the two or more solutions are fed; after the two or more solutions are fed to the addition tank, the solution containing a polymerizable organic compound or polymer is fed to the addition tank; the fine particle obtained by the step show a particle size distribution with a standard deviation of 1.0 or less, preferably 0.8 or less, more preferably 0.7 or less; the fine particle obtained by the step have a mean particle size of 1-10 nm, preferably 1-5 nm; Requirement (1) is satisfied, and the flows of different rotational directions are formed by rotating stirring impellers in a pair disposed in the addition tank so as to face each other and to be separated from each other in different directions; Requirement (2) is satisfied, and in the mixing chamber, a stirring flow is formed for mixing the fed two or more solutions; Requirement (2) is satisfied, and a flow is formed for discharging the fine particles produced in the mixing chamber from the mixing chamber to outside the mixing chamber through the opening; Requirement (2) is satisfied, and the first solution contains a Group II element, the second solution contains a Group VI element, and fine particles comprising the Group II element and the Group VI element are prepared as the semiconductor fine particles; Requirement (2) is satisfied, and the first solution and/or the second solution contain at least one element selected from transition metals and rare earth metals, or alternatively a third solution containing at least one element selected from transition metals and rare earth metals is fed to the addition tank with the first solution and the second solution, and fine particles activated by the transition metals or rare earth metals are prepared as the semiconductor fine particles; Requirement (2) is satisfied, and at least one of the solvent, the first solution and the second solution contains an anionic surfactant and/or nonionic surfactant; and/or Requirement (2) is satisfied, and at least one of the solvent, the first solution and the second solution contains a polymerizable organic compound or polymer.

### BEST MODE FOR CARRYING OUT THE INVENTION

Hereafter, the method for producing semiconductor fine particles of the present invention will be explained in detail.

The production method of the present invention comprises a step of preparing two or more solutions each containing at least one element selected from Group II to Group VI and separately or simultaneously feeding the solutions to an addition tank with mixing the two or more solutions fed to the addition tank by stirring to produce fine particles comprising two or more elements selected from Group II to Group VI. Further, the production method of the present invention is required to satisfy Requirement (1) and/or (2).

Requirement (1) is that flows of different rotational directions should be formed by stirring the two or more solutions fed to the addition tank. The flows of different rotational directions can be formed by disposing stirring impellers in a pair in the addition tank so as to face each other and rotating the stirring impellers in different directions. The flows of different rotational directions formed in the addition tank collide against each other or one another to form turbulent diffusions of high speed. As a result, the flows in the addition tank can be prevented from being in a stationary state, and fine particles having extremely small and uniform particle sizes can efficiently be produced When activated-type light-emitting semiconductor fine particles are produced, in particular, light emission luminance can be improved because fine particles showing a narrow particle size distribution can be obtained

As an example of stirring apparatus that can be used for the production method of the present invention, the stirring apparatus described in Japanese Patent Laid-open publication No. 10-43570, FIGS. 1 to 3 can be mentioned. This apparatus is an apparatus for producing photographic emulsions, in which fine particles having fine and uniform particle sizes are produced by increasing instantaneous stirring performance in a tank. However, the present invention is not limited to an embodiment in which semiconductor fine particles are produced by using the apparatus described in the above reference, and any embodiments fall within the scope of the present invention so long as a configuration is employed in which flows of different rotational directions can be formed in a tank so that the flows in the tank can be prevented from being in a stationary state.

As an embodiment of the method of the present invention, there can be mentioned the production method in which the step is performed by using a stirring apparatus provided with a cylindrical addition tank having an inner diameter D, stirring impellers in a pair (impeller diameter: d) disposed in the addition tank so as to face each other and so as to be separated from each other, and two or more of feed openings formed on the addition tank. The stirring impellers in a pair have a configuration that they are disposed on the same rotational axis and separated from each other, and they can rotate in inverse directions. The feed openings may be openings formed on wall of the addition tank. The feed openings are preferably provided between one of the stirring impellers in a pair and the other stirring impeller. For example, when one stirring impeller is provided at an upper position of the addition tank along the height direction and the other stirring impeller is provided at a lower position on the same rotational axis, the feed openings are preferably provided between the stirring impellers in a pair along the height direction. When the two or more solutions are separately fed from different feed openings, two of the feed openings are more preferably provided at facing positions (positions separated by the inner diameter D), and solutions each fed from one of the two feed openings are preferably fed between the stirring impellers in a pair and immediately mixed in turbulent diffusions formed by the flows of different rotational directions.

In the stirring apparatus, average resident time t of solutions to be stirred is preferably 0.05-5 seconds. The average resident time t is defined by the following equation.

t=Vm/(ΣQi)

Vm: Effective stirring volume (mL)

ΣQi: Total flow rate of solutions fed into addition tank (mL/sec)

In order to improve the instantaneous stirring performance, various factors are preferably optimized, which include average flow rates of solutions passing through the feed openings, ratio of stirring impeller diameter and inner diameter of the addition tank, shearing forth generated between the stirring impellers and inner wall by rotation of stirring impellers and so forth.

If average flow rate u of a solution to be stirred is too small at the time of passing through a feed opening, solutions in the addition tank may unfavorably back flow to the feed side due to centrifugal force generated by rotation of the stirring impellers. u is preferably 20-200 cm/sec. u is defined by the following equation.

u=4Q/πφ²

Q: Flow rate of solution (mL/sec)

φ: Diameter of feed opening (cm)

If the ratio of stirring impeller diameter d and inner diameter of addition tank D (d/D) is too small, stirring efficiency is unfavorably reduced. On the other hand, if it is too large, inflow of the solution from the feed opening is prevented. From these viewpoints, d/D is preferably 0.5-0.9.

The shearing forth τ generated between the stirring impellers and the addition tank wall increases in proportion to the rotation number of stirring impellers, and the instantaneous stirring performance can be improved by increasing the shearing forth. τ is preferably 500 sec⁻¹, more preferably 800⁻¹. τ is defined by the following equation.

τ=πdN/σ

N: Rotation number of stirring (rps)

σ: (D−d)/2 (cm)

Further, Requirement (2) defines the conditions that (i) a solvent should be introduced into the addition tank beforehand, (ii) a mixing chamber having an opening should be disposed below a liquid surface of the solvent in the addition tank, and (iii) the two or more solutions should be fed into the mixing chamber with controlling flow rates of the solutions. If Requirement (2) is satisfied, produced particles can be made finer particles and the particle sizes can be made more uniform compared with the case of dropping the solutions from above the liquid surface. This method is a method similar to the method called double jet method used for the production of emulsions for photographic films, and by using this method for the production of semiconductor particles, semiconductor particles having desired and uniform particle sizes can be produced.

In the present invention, feeding flow rate of each solution is preferably determined based on a stoichiometric ratio. That is, the feeding flow rate of each solution is preferably controlled so that molar ratio of elements contained in the solutions fed per unit time (in particular, molar ratio of Group II element or Group III element and Group V element or Group VI element) should correspond to a desired stoichiometric ratio. Therefore, in an embodiment in which two solutions containing elements that react in a ratio of 1:1 are mixed, the feeding flow rates are controlled so that the addition volumes per unit time of the two solutions should be equal to each other.

Method for controlling feeding flow rates of solutions is not particularly limited, and various flow rate-controlling methods can be utilized. For example, by using an orifice, gas pressurizing apparatus, pump of which rotation number can be controlled, bulb and so forth, the solutions can be fed with controlled flow rates. As for detection of the flow rates, when the solutions are fed into liquid via feeding pipes, for example, generally used is a method of providing sensors in the middle of the feeding pipes to detect the flow rates.

As a preferred embodiment of the production method of the present invention, there can be mentioned an embodiment in which a state of inside of the addition tank is detected and at least one solution is fed into the mixing chamber with controlling its flow rate based on the detected amount obtained for that solution For example, there can be employed a method of continuously monitoring potential of an electrode in the addition tank and feeding back a potential deviation as a signal optionally after amplification of the potential deviation to control addition flow rate of the solution so that the potential in the addition tank should be kept constant and so forth. As the object of the monitoring, potential, pH, absorbance of the solution in the addition tank and so forth can be exemplified. However, the object is not limited to these.

In the present invention, a mixing chamber is preferably provided below liquid surface of the solvent in the addition tank (i.e., such a position that the mixing chamber should be present in the solvent), and the solutions are preferably fed into such a mixing chamber. By mixing the solutions with use of the mixing chamber disposed in the solvent, semiconductor fine particles having more uniform particle sizes can be obtained. The mixing chamber is disposed below liquid surface of the solvent introduced into the addition tank and has an opening. Therefore, the solvent introduced into the addition tank enters into inside of the mixing chamber through the opening, and the inside of the mixing chamber is filled with the solvent. The two or more solutions fed into the mixing chamber are diluted with the solvent in the mixing chamber, and immediately mixed uniformly by a stirring flow formed in the mixing chamber. In this way, rapider and more uniform mixing becomes possible by mixing the two or more solutions with use of the mixing chamber, and this contributes to production of particles having finer and more uniform particle sizes. By providing stirring impellers in the mixing chamber, the stirring flow can be easily formed in the mixing chamber.

If the produced fine particles reside too long in the mixing chamber, they may bind to other produced particles or further react with the solutions fed into the mixing chamber to form larger particles. In order to prevent this and thereby more stably obtain fine particles having fine and uniform particle size, a stirring flow is preferably formed in the mixing chamber to quickly cause the reaction of the solutions, and a flow for quickly discharging the particles produced by the reaction from the mixing chamber through the opening is preferably formed in the mixing chamber. If a stirring flow as well as a flow for discharging the produced particles from the mixing chamber are formed in the mixing chamber as described above, the fine particles are quickly discharged from the mixing chamber, and thus the particles can be prevented from forming larger particles. For example, openings can be provided on two sites (e.g., at lower end portion and upper end portion) of the mixing chamber (in the shape of cylinder, polygonal prism etc.), and the produced particles can be quickly discharged out of the mixing chamber by feeding the solutions from one opening (e.g., opening at the lower end portion) and forming a flow toward to the other opening (e.g., opening at the upper end portion) in the mixing chamber. Such a flow can be formed by the second stirring impeller provided in the mixing chamber. Shape of the second stirring impeller is designed so that a flow of desired direction can be formed by stirring.

An example of the addition tank having a mixing chamber that can be used for the production method of the present invention is disclosed in, for example, Japanese Patent Publication (Kokoku) No. 55-10545, FIGS. 5 to 10. The mixing chamber disclosed in this reference has functions for simultaneously performing dilution of reaction solutions, thorough mixing of content in the addition tank and uniformization of solvent in the addition tank (bulk solution) to improve uniformity of the particles. In the production method of the present invention, structure etc. of the mixing chamber are not particularly limited so long as a similar effect is obtained by using the mixing chamber, and any of embodiments utilizing the mixing chamber described in the above reference, embodiments utilizing a similarly functioning mixing chamber other than those exemplified and so forth fall within the scope of the present invention. Further, in the present invention, the term “mixing chamber” must be construed in its broadest sense, and its shape is not particularly limited so long as it is disposed in the addition tank and functions in the same way as described above.

The solutions used for the production method of the present invention are solutions of a compound containing at least one element selected from Group II to Group VI. Preferred is an embodiment in which a first solution of a compound containing at least one Group II element or Group III element and a second solution of a compound containing at least one Group V element or Group VI element are used as the solutions. More preferred is an embodiment in which a first solution of a compound containing at least one Group II element and a second solution of a compound containing at least one Group VI element are used as the solutions.

In the production method of the present invention, Group II to Group VI elements contained in the aforementioned solutions become elements constituting fine particles to be produced. For example, semiconductor fine particles of Group II-VI compounds can be produced by using a solution of a compound containing a Group II element and a solution of a compound containing a Group VI element. Therefore, the compounds to be dissolved in the solutions can be determined depending on elemental composition of semiconductor particles to be produced. Examples of compounds containing a Group II element include halogenides (e.g., chloride) salts of various acids (e.g., sulfate, acetate, nitrate, phosphate, perchlorate, organic acid salt etc.), complex salts (e.g., acetylacetonato complex etc.) and organometallic compounds (e.g., dimethyl compounds, diethyl compounds etc.) containing Group II elements Examples of compounds containing a Group III element include halogenides (e.g., chloride etc.), complex salts (e.g., acetylacetonato complex etc.) and organometallic compounds (e.g., trimethyl compounds, triethyl compounds etc.) containing Group III elements. These compounds may be either an anhydride or hydrate. Examples of compounds containing Group V and Group VI elements include alkali metal salts (sodium salt, potassium salt etc.) and organic silicon compounds (trimethylsilyl salt etc.) of each element. As sulfur-containing compounds among compounds containing a Group VI element, sodium thiosulfate, thiourea, thioacetamide etc. can also be used in addition to those mentioned above. Although the concentration of these raw materials used for a reaction depends on the kind of the solvent used for the reaction, it is preferably 1×10⁻⁶ to 1 mol/L, more preferably 1×10⁻⁴ to 0.1 mol/L.

As solvent of the aforementioned solutions, either hydrophilic or hydrophobic solvent may be used, and any solvent can be used so long as a raw material compound can be dissolved therein. Examples of solvents that can be used include water, alcohols (e.g., methanol, ethanol etc.), polyhydric alcohols (e.g., ethylene glycol, diethylene glycol, polyethylene glycol etc.), glycol derivatives (e.g., ethylene glycol monomethyl ether etc.), amines (e.g., ethanolamine, hexadecylamine, hexaoctylamine, ethylenediamine, pyridine etc.), phosphines and oxides thereof (e.g., trioctylphosphine, trioctylphosphine oxide, trihexylphosphine etc.), mercapto compounds (3-mercaptotrimethylsiloxane, mercaptoethanol, 1-mercapto-2,3-propanediol etc.) and polar solvents (e.g., formamide, N,N-dimethylformamide, acetonitrile, acetone etc.). One or more solvents may be used in combination. However, when two or more solvents are used, combination of hydrophilic solvents or combination of hydrophobic solvents is preferably used considering solubility and reactivity of the raw materials. The exemplified solvents may be introduced into the addition tank beforehand, and the solvents may also be added with various additives beforehand.

By adding an activating agent to the aforementioned solutions beforehand, a part of metal atoms are replaced with the activating agent, and thus activated type semiconductor fine particles can be produced, in which the replacing metal functions as a light emission center. For example, by replacing a zinc atom in zinc sulfide with another metal atom, the replacing metal can be allowed to function as a light emission center. The activated type semiconductor fine particles are known to emit light unique to kind of the activating agent atom, and can emit also blue, green or red color. As the activating agent used for zinc sulfide, metals such as aluminum, manganese, copper, silver, cerium, terbium and europium are effective. These activating agents can be used in combination with fluorine, chlorine or the like as required for compensation of electric charges etc. The activating agents may be used individually or in a combination of two or more of them. Further, the activating agent may be contained in the aforementioned solutions, or a solution containing the activating agent may be fed to the addition tank in addition to the solutions containing elements constituting the semiconductor particles. These methods may be used in combination. The activating agent is preferably contained in any of the aforementioned solutions, and the activating agent is particularly preferably contained in a solution containing a Group II or Group III element.

In the present invention, a surfactant may be added to the aforementioned solutions. Examples of surfactants that can be used include fatty acid salts, alkylsulfuric acid ester salts, alkylbenzenesulfonates, alkylnaphthalenesulfonates, dialkylsulfosuccinates, alkylphosphoric acid ester salts, naphthalenesulfonic acid formalin condensates, polyoxyethylenealkylsulfuric acid ester salts and so forth as anionic surfactants; and polyoxyethylene alkyl ethers, polyoxyethylene alkyl allyl ethers, polyoxyethylene fatty acid esters, sorbitan fatty acid esters, polyoxyethylene sorbitan fatty acid esters, polyoxyethylene alkylamines, glycerine fatty acid esters, oxyethylene oxypropylene block copolymers and so forth as nonionic surfactants. One kind of these surfactants may be solely used or two or more kinds of them may be used in combination. The surfactant may be added to a dispersion system after the production of particles.

Although the preferred range of the amount of the surfactant to be added may vary depending on the size of particles to be produced, it is usually preferably 200 parts by weight or less, more preferably 100 parts by weight or less, of the weight of the produced particles. The concentration of the surfactant used is preferably 20 weight % or less, more preferably 10 weight % or less.

In the present invention, an organic binder may be added to the aforementioned solutions. If an organic binder is added, composites comprising the organic binder can be adsorbed on the surfaces of the produced particles, and hence it becomes possible to suppress aggregation of the particles and prepare a dispersion having an excellent dispersing property. Examples of the organic binder that can be used include acrylic acid, methacrylic acid, esters such as methyl methacrylate, homopolymers and copolymers of vinyl monomers such as vinyl acetate and styrene, polyethylene oxide, polyvinyl alcohol, polyvinylpyrrolidone, polyacrylic acid, polyacrylamide, polymethyl methacrylate, copolymer of acrylonitrile and styrene, latex of styrene/butadiene etc., polycarbonate, fluorinated or deuterated polymethyl methacrylate, polyimide, epoxy polymer, sol/gel polymer and so forth. The polymer used as the organic binder may be either a homopolymer or a copolymer, and a photo-curing resin polymer may be used solely or mixed as required. As in the case of the surfactant, one or more of these additives may be used in combination, and they may be added to a dispersion system after the production of particles, besides addition to the aforementioned solutions.

Usually, the amount of the organic binder to be added is preferably 500 parts by weight or less of the weight of produced particles. The concentration of the organic binder to be used is preferably 10 weight % or less, more preferably 5 weight % or less, of the solvent in which the organic binder is dissolved.

A polymerizable organic compound (e.g., vinyl monomer) or a polymer thereof may be added to the aforementioned solutions etc. and allowed to polymerize to produce polymer composites. The polymerization can be initiated by, for example, adding a polymerization initiator such as 2,2′-azobisisobutyronitrile (AIBN) to the solutions together with a monomer or by ultraviolet irradiation. When AIBN is used, degree of polymerization can be controlled by using a radical scavenger, as required. When polymerization is initiated by ultraviolet irradiation, the wavelength of ultraviolet rays used for these compounds is preferably 300-380 nm. The polymerizable organic compound may be added not only to the aforementioned solutions, but also to a dispersion system after the production of particles.

An adsorptive compound (dispersing agent) can also be added to the aforementioned solutions etc. to produce particles of which surfaces are modified with the adsorptive compound. As the adsorptive compound, compounds containing an adsorptive group such as —SH, —CN, —NH₂, —SO₂OH, —SOOH, —OPO(OH)₂ and —COOH are effective. Further, as the aforementioned dispersing agent, hydrophilic macromolecular compounds can be used, and examples thereof include hydroxyethylcellulose, polyvinylpyrrolidone, polyethylene glycol and so forth.

The surfaces of the particles of the present invention may be treated beforehand to obtain, for example, a good dispersion property in the aforementioned polymers. For example, the thiol surface modification (M. L. Steigerwald et al., J. Am Chem. Soc., 110, 3046, 1988), the photocatalytic reaction method (T. Hayashi et al., J. Phys. Chem., 96, 2866, 1992) and so forth can be used. However, the surface treatment method is not limited to these examples.

In addition, various additives such as antistatic agent, antioxidant, UV absorber and plasticizer can be used for the aforementioned solutions etc. as required. Further, when the particles are used to label a nucleic acid, antibody, antigen or the like, the particle surfaces are particularly preferably made hydrophilic with amine, thiol or the like and used.

Further, the obtained dispersion may be ripened by heating or heating under pressure. Furthermore, particles may be separated from the dispersion to obtain powder of the particles and then they may be ripened by heating. For example, the heating favorably ripens the particles to improve crystallinity of the particles and enables control of the particle size. Usually, the particle size can be controlled so as to become larger. Although the preferred temperature range of heating for dispersion slightly varies depending on the kind of the solvent used, it is preferably 50-100° C. The temperature range of heating for particles is preferably 150-600° C., more preferably 250-500° C. Temperature of the heating is preferably maintained constant in the aforementioned ranges.

Since the dispersion of fine particles obtained by the aforementioned step contains excess cations or anions therein, the dispersion is preferably subjected to a treatment for removing these ions and then used for various purposes. The excess cations, anions etc. can be removed by precipitating the particles by centrifugation to separate them from the solution. Further, these ions can also be removed by a known ion exchange method using an ion exchange resin or an ultrafiltration membrane. Since aggregation of particles can be suppressed by removing excess cations or anions, the removal is particularly effective when the aforementioned absorptive compound or the like is not added.

By the production method of the present invention, there can be obtained, for example, such particles as described in J. Am. Chem. Soc. 1993, 115, 8706-8715, “Synthesis and Characterization of Nearly Monodisperse CdE (E=S, Se, Te) Semiconductor Nanocrystallites”; and Hyomen Kagaku (Surface Chemistry), 22, 5, “Light-Emitting Mechanism and Local Structure Analysis of Organic/Inorganic Composite Type ZnS; Mn Nanocrystal Fluorescent Substances”.

Semiconductor fine particles produced by the method of the present invention can be used for the optical switching element described in Japanese Patent Laid-open Publication No. 2000-321607, the optical memory element using interference of multiple scattered light described in Japanese Patent Laid-open Publication No. 2000-99986, the optical memory element described in Japanese Patent Laid-open Publication No 2000-81682, the EL element described in Japanese Patent Laid-open Publication No. 2001-18677, the optical recording medium described in Japanese Patent Laid-open Publication No. 2000-178726, the photoelectric conversion elements described in Japanese Patent Laid-open Publication Nos. 07-95774 and 07-75162, the diagnosis element described in British Patent No. 2342651, the analyzing element described in U.S. Pat. No. 5,990,479 and so forth.

For the aforementioned purposes, the particles can be provided in the form of a thin film formed from a dispersion obtained by dispersing the obtained semiconductor fine particles in a solvent with a binder etc. In order to form a thin film, there can be used application type coating methods such as a roller coating method, dip coating method etc.; metering type coating methods such as an air knife coating method, blade coating method etc.; and as methods enabling application of the application type and metering type coating methods to the same region, the wire bar coating method disclosed in Japanese Patent Publication No. 58-4589, the slide hopper coating method, extrusion coating method, curtain coating method etc. described in U.S. Pat. Nos. 2,681,294, 2,761,419, 2,761,791 etc. Further, in order to form a thin film, a general-purpose machine for performing spin coating method or spray coating method is also preferably used. Further, in order to form a thin film, there are also preferably utilized wet printing methods including the three major printingmethods of relief printing, offset printing and gravure printing, as well as intaglio printing, rubber plate printing, screen printing and so forth. From these methods, a preferred film forming method can be selected depending on viscosity of the dispersion and wet thickness of thin film Viscosity of the dispersion of semiconductor fine particles largely depends on kind and dispersibility of semiconductor fine particles to be produced and kind of a solvent to be used, additives (surfactant, binder etc.) to be used and so forth. For a high viscosity dispersion (e.g., 0.1-500 Pa·s (0.1-500 Poise)), the extrusion method, casting method, screen printing method or the like is preferably used. For a low viscosity dispersion (e.g, 0.1 Pa·s or lower (0.1 Poise or lower)), the slide hopper coating method, wire bar coating method or spin coating method is preferably used, and a uniform film can be formed by such a method. When the coating amount exceeds a certain level, the coating can be performed by the extrusion coating method even with a low viscosity dispersion. Thus, an appropriate wet film forming method may be selected depending on the viscosity of coating dispersion, coating amount, support, coating rate etc.

The aforementioned thin film having a laminate structure can be used for the aforementioned purposes. For example, there can be mentioned a thin film formed by applying dispersions each containing semiconductor fine particles having a different grain size in multiple layers, a thin film formed by applying dispersions each containing semiconductor fine particles of different kind of compound species (or different binder, additive etc.) in multiple layers and so forth. It is also effective to apply the same dispersion in multiple layers when a film thickness enough for obtaining sufficient performances cannot be obtained by a single coating. The extrusion coating method and the slide hopper coading method are suitable for multilayer coating. Further, when multilayer coating is performed, multiple layers may be simultaneously applied, or several to several tens of layers may be successively applied. Further, when multiple layers are successively applied, the screen printing method may also be preferably used.

### EXAMPLES

The present invention will be more specifically explained with reference to the following examples. Materials, reagents, proportions, procedures and so forth mentioned in the following examples can be appropriately changed unless such changes depart from the spirit of the present invention. Accordingly, the scope of the present invention is not limited to these specific examples

### Example 1

[Preparation of Particles A to G]

The apparatus described in Japanese Patent Laid-open Publication No. 10-43570, FIGS. 1 to 3 was used.

Stirring impellers in a pair in a reaction cell were rotated at 3,000 rpm, and a first solution and second solution mentioned in Table 1 were added to the reaction cell each at a flow rate of 200 mL/min to prepare a dispersion (t=2.3 sec, u=25 cm/sec, d/D=0.6, τ=800 sec⁻¹). As for Particles F and G, a third solution mentioned in Table 1 was added immediately thereafter, and stirring was performed for 15 minutes to prepare a dispersion.

The obtained dispersion was centrifuged at 8,000 rpm for 15 minutes to separate precipitates from the liquid phase, and the precipitates were washed with water and methanol to obtain particles.

[Preparation of Particles H to K]

A first solution mentioned in Table 1 was placed in a beaker and added with a second solution mentioned in Table 1 at a rate of 10 mL/min with stirring by a stirrer to prepare a dispersion. As for Particle K, the third solution mentioned in Table 1 was added immediately thereafter, and stirring was performed for 15 minutes to prepare a dispersion.

The obtained dispersion was centrifuged, and washing was performed as described above to obtain particles.

[Evaluation of Particle Size and Size Distribution]

Particles A to K obtained were photographed by using a transmission microscope, and the average particle size and the size distribution of about 200 particles were measured. The size distributions are shown in Table 1 as standard deviations together with the particle sizes.

TABLE 1

| | | | | Measurement result | | |
|---|---|---|---|---|---|---|
| | Added solution | | | Average | | |
| Par- | First | Second | Third | particle | Standard | |
| ticle | solution | solution | solution | size (nm) | deviation | Note |
| A | (i) | (iii) | — | 3.2 | 0.62 | Invention |
| B | (ii) | (iii) | — | 3.2 | 0.63 | Invention |
| C | (i) | (iv) | — | 3.3 | 0.68 | Invention |
| D | (i) | (v) | — | 3.5 | 0.61 | Invention |
| E | (ii) | (v) | — | 3.3 | 0.65 | Invention |
| F | (i) | (iii) | (vi) | 3.5 | 0.63 | Invention |
| G | (ii) | (iii) | (vi) | 3.3 | 0.64 | Invention |
| H | (i) | (iii) | — | 3.6 | 1.12 | Comparative |
| I | (i) | (iv) | — | 3.4 | 1.08 | Comparative |
| J | (i) | (v) | — | 3.6 | 1.21 | Comparative |
| K | (i) | (iv) | (vi) | 3.5 | 1.15 | Comparative |

Remark:
Compositions of (i) to (vi) are shown in Table 2.

TABLE 2

| | (i) | (ii) | (iii) | (iv) | (v) | (vi) |
|---|---|---|---|---|---|---|
| Zinc acetate | 22 g | 22 g | | | | |
| dihydrate | | | | | | |
| Manganese acetate | | 0.8 g | | | | |
| dihydrate | | | | | | |
| Sodium sulfate | | | 24.7 g | 24.7 g | 24.7 g | |
| nonahydrate | | | | | | |
| Sodium | | | | 7 g | | |
| dodecyl- | | | | | | |
| benzenesulfonate | | | | | | |
| Acrylic acid | | | | | 20 g | 20 g |
| Water | 1000 | 1000 | 1000 | 1000 | 1000 | 1000 |
| | ml | ml | ml | ml | ml | ml |

[Measurement of Photoluminescence Intensity]

Photoluminescence intensity measurement was performed for Particles B, E, G, I, J and K among the obtained particles by using a fluorospectrophotometer (FL-4500, Hitachi). Excitation was attained at 350 nm, and fluorescence intensity was measured at 585 nm and represented as a relative value based on the intensity of Particle I, which was taken as 1. The results are shown in Table 3.

TABLE 3

| Particle | Relative intensity | Note |
|---|---|---|
| B | 1.16 | Invention |
| E | 1.29 | Invention |
| G | 1.25 | Invention |
| I | 1.00 | Comparative |
| J | 1.14 | Comparative |
| K | 1.12 | Comparative |

### Example 2

[Preparation of Particles A′ to E′]

The apparatus described in Japanese Patent Publication No. 55-10545, FIGS. 5 to 10 was used as a mixer. That is, a mixer having two of concentric stirring impellers was disposed in a cylindrical reaction tank having a hemispheric bottom, and the mixer was positioned so that the lower stirring impeller should locate at a position of 15 mm from the bottom of the reaction tank. Water (800 mL) was introduced into the reaction tank, and water temperature was maintained at 30° C. The whole body of the mixer was immersed in water.

A first solution and second solution mentioned in Table 4, which were maintained at 30° C., were fed into the mixer in the immersed in water via reaction solution addition pipes to prepare a dispersion. As for Particle E′, the third solution mentioned in Table 4 was added immediately thereafter, and stirring was performed for 15 minutes to prepare a dispersion.

The obtained dispersion was centrifuged at 8,000 rpm for 15 minutes to separate precipitates from the liquid phase, and the precipitates were washed with water and methanol to obtain particles.

[Preparation of Particles F′]

Particle F′ was prepared in the same apparatus and the same manner as in the preparation of Particle A′ except that the addition pipes connected to the mixer were not used, but the first and second solutions were added from a position above the liquid surface.

[Preparation of Particles G′ to J′]

A first solution mentioned in Table 4 was placed in a beaker and added with a second solution mentioned in Table 4 at a rate of 100 mL/min with stirring by a stirrer to prepare a dispersion. As for Particle J′, the third solution mentioned in Table 4 was added immediately thereafter, and stirring was performed for 15 minutes to prepare dispersion.

The obtained dispersion was centrifuged at 8,000 rpm for 15 minutes to separate precipitates from the liquid phase, and the precipitates were washed with water and methanol to obtain particles.

[Evaluation of Particle Size and Size Distribution]

Average particle size and size distribution were measured for Particles A′ to J′ in the same manner as in Example 1. The results are also shown in Table 4.

TABLE 4

| | | | | Measurement result | | |
|---|---|---|---|---|---|---|
| | Added solution | | | Average | | |
| Par- | First | Second | Third | particle | Standard | |
| ticle | solution | solution | solution | size (nm) | deviation | Note |
| A′ | (i) | (iii) | — | 3.0 | 0.60 | Invention |
| B′ | (ii) | (iii) | — | 3.1 | 0.62 | Invention |
| C′ | (ii) | (iv) | — | 3.2 | 0.62 | Invention |
| D′ | (ii) | (v) | — | 3.3 | 0.65 | Invention |
| E′ | (i) | (iii) | (vi) | 3.2 | 0.63 | Invention |
| F′ | (i) | (iii) | — | 3.7 | 1.22 | Comparative |
| G′ | (i) | (iii) | — | 3.4 | 1.10 | Comparative |
| H′ | (ii) | (iii) | — | 3.3 | 1.12 | Comparative |
| I′ | (ii) | (iv) | — | 3.3 | 1.10 | Comparative |
| J′ | (i) | (iii) | (vi) | 3.4 | 1.15 | Comparative |

TABLE 5

| | (i) | (ii) | (iii) | (iv) | (v) | (vi) |
|---|---|---|---|---|---|---|
| Zinc acetate | 22 g | 22 g | | | | |
| dihydrate | | | | | | |
| Manganese acetate | | 0.8 g | | | | |
| dihydrate | | | | | | |
| Sodium sulfate | | | 24.7 g | 24.7 g | 24.7 g | |
| nonahydrate | | | | | | |
| Sodium | | | | 7 g | | |
| dodecyl- | | | | | | |
| benzenesulfonate | | | | | | |
| Acrylic acid | | | | | 20 g | 20 g |
| Water | 1200 | 1200 | 1200 | 1200 | 1200 | 1200 |
| | ml | ml | ml | ml | ml | ml |

[Measurement of Photoluminescence Intensity]

Photoluminescence intensity measurement was performed for Particles B′, C′, D′, H′ and I′ among the obtained particles in the same manner as in Example 1, and fluorescence intensity was represented as a relative value based on the intensity of Particle H′, which was taken as 1. The results are shown in Table 6.

TABLE 6

| Particle | Relative intensity | Note |
|---|---|---|
| B′ | 1.18 | Invention |
| C′ | 1.33 | Invention |
| D′ | 1.35 | Invention |
| H′ | 1.00 | Comparative |
| I′ | 1.13 | Comparative |

From the results shown in Table 4, it was found that the particles produced by the production method of the present invention were fine particles having a narrow size distribution. As a result of that, it was found that the particles produced by the production method of the present invention (Particles B′, C′ and D′) showed higher fluorescence intensity as clearly seen from the results shown in Table 6.

What is claimed is:

1. A method for producing semiconductor fine particles comprising a step of preparing two or more solutions each containing at least one element selected from Group II to Group VI and separately or simultaneously feeding the solutions to an addition tank with mixing the two or more solutions fed to the addition tank by stirring to produce fine particles comprising two or more elements selected from Group II to Group VI, which satisfies the following Requirements (1) and/or (2).
Requirement (1)
Flows of different rotational directions should be formed by stirring the two or more solutions fed to the addition tank.
Requirement (2)
A solvent should be introduced into the addition tank beforehand, a mixing chamber having an opening should be disposed below liquid surface of the solvent in the addition tank, and the two or more solutions should be fed to the mixing chamber with controlling flow rates of the solutions.

2. The method for producing semiconductor fine particles according to claim 1, wherein two solutions each containing at least one element selected from Group II to Group VI are prepared, and the Requirement (1) is satisfied.

3. The method for producing semiconductor fine particles according to claim 1, wherein, as the solutions each containing at least one element selected from Group II to Group VI, a first solution of a compound containing at least one Group II element or Group III element and a second solution of a compound containing at least one Group V element or Group VI element are prepared, and the Requirement (2) is satisfied.

4. The method for producing semiconductor fine particles according to claim 2, wherein, as the solutions each containing at least one element selected from Group II to Group VI, a first solution of a compound containing at least one Group II element and a second solution of a compound containing at least one Group VI element are prepared.

5. The method for producing semiconductor fine particles according to claim 2, wherein the flows of different rotational directions are formed by rotating in different directions a pair of stirring impellers disposed in the addition tank so as to face each other and to be separated from each other.

6. The method for producing semiconductor fine particles according to claim 2, wherein a mixed solution prepared in the addition tank contains at least one element selected from transition metals and rare earth metals.

7. The method for producing semiconductor fine particles according to claim 2, wherein a mixed solution prepared in the addition tank contains an anionic surfactant and/or nonionic surfactant.

8. The method for producing semiconductor fine particles according to claim 2, wherein a mixed solution prepared in the addition tank contains a polymerizable organic compound or polymer.

9. The method for producing semiconductor fine particles according to claim 1, wherein the fine particle obtained by the step show a particle size distribution with a standard deviation of 1.0 or less.

10. The method for producing semiconductor fine particles according to claim 1, wherein the fine particle obtained by the step show a particle size distribution with a standard deviation of 0.8 or less.

11. The method for producing semiconductor fine particles according to claim 1, wherein the fine particle obtained by the step show a particle size distribution with a standard deviation of 0.7 or less.

12. The method for producing semiconductor fine particles according to claim 1, wherein the fine particle obtained by the step have a mean particle size of 1-10 nm.

13. The method for producing semiconductor fine particles according to claim 1, wherein the fine particle obtained by the step have a mean particle size of 1-5 nm.

14. The method for producing semiconductor fine particles according to claim 3, wherein, in the mixing chamber, a stirring flow is formed for mixing the fed two or more solutions.

15. The method for producing semiconductor fine particles according to claim 14, wherein a flow is formed for discharging the fine particles produced in the mixing chamber from the mixing chamber to outside the mixing chamber through the opening.

16. The method for producing semiconductor fine particles according to claim 3, wherein the first solution contains a Group II element, the second solution contains a Group VI element, and fine particles comprising the Group II element and the Group VI element are prepared as the semiconductor fine particles.

17. The method for producing semiconductor fine particles according to claim 3, wherein the first solution and/or the second solution contain at least one element selected from transition metals and rare earth metals, or alternatively a third solution containing at least one element selected from transition metals and rare earth metals is fed to the addition tank with the first solution and the second solution, and fine particles activated by the transition metals or rare earth metals are prepared as the semiconductor fine particles.

18. The method for producing semiconductor fine particles according to claim 3, wherein at least one of the solvent, the first solution and the second solution contains an anionic surfactant and/or nonionic surfactant.

19. The method for producing semiconductor fine particles according to claim 3, wherein at least one of the solvent, the first solution and the second solution contains a polymerizable organic compound or polymer.
